(19) United States
(12) Patent Application Publication
(10) Pub. No.: US 2025/0147724 A1
(43) Pub. Date: May 8, 2025

(54) BINARY FLOATING-POINT IN-MEMORY MULTIPLICATION DEVICE

(71) Applicant: FlashSilicon Incorporation, Diamond Bar, CA (US)

(72) Inventor: LEE WANG, Diamond Bar, CA (US)

(21) Appl. No.: 18/500,608

(22) Filed: Nov. 2, 2023

(51) Int. Cl. G06F 7/487; G06F 5/01; G06F 7/485; H03K 19/21

(52) U.S. Cl. CPC G06F 7/4876; G06F 5/012; G06F 7/485; H03K 19/21

(57) ABSTRACT

A floating-point in-memory multiplication device achieving one-step floating-point multiplication operation is disclosed. The device performs multiplication on a multiplicand and a multiplier and generates a first product. Each of the multiplicand, the multiplier and the first product is a binary floating-point number in IEEE 754 format and contains a sign bit, a q-bit exponent and a (p−1)-bit significand. The device comprises a XOR gate device, a decoder circuit, an adder circuit, a binary in-memory multiplier circuit and an encoder circuit. The XOR gate device receives the sign bits of the multiplicand and the multiplier to generate a sign bit of the first product. The adder circuit adds up the q-bit exponents of the multiplicand and the multiplier to generate a (q+1)-bit temporary exponent. The binary in-memory multiplier circuit performs multiplication on a first and a second p-bit significands to generate a 2p-bit second product.

### BACKGROUND OF THE INVENTION

### Field of the Invention

The invention is related to a binary floating-point in-memory multiplication device for two binary floating-point number operands. In particular, in order to achieve one-step floating-point multiplication operation for improving the computation efficiency and saving computation power, the binary floating-point in-memory multiplication device of the invention comprises (1) two binary floating-point decoders for converting the exponent bits into two most significant bits (aₚ₋₁/bₚ₋₁) of two p-bit significands for two inputted floating-point number operands; (2) multiple memory arrays storing a base-2ⁿ multiplication code table for the significand-bit multiplication operation; (3) an adder circuit for the exponent-bit addition operation; (4) a binary floating-point number encoder for converting the resultant 2p-bit multiplied number code from the multiplication of two prior binary p-bit significands into the standard binary (p−1)-bit significand number code in IEEE 754 format ready for further operation and storage.

### Description of the Related Art

In the modern Von Neumann computing architecture as shown in FIG. 1, the Central Process Unit (CPU) 10 executes logic operations according to the instructions and data from the main memory 11. The CPU 10 includes a main memory 11, Arithmetic and Logic Unit (ALU) 12, an input/output equipment 13 and program control unit 14. Prior to the computation process, CPU 10 is set by the program control unit 14 to point to the initial address code for the initial instruction in the main memory 11. The digital data are then processed with the ALU 12 according to the sequential instructions in the main memory 11 accessed by the clock-synchronized address pointer (instruction cache) in the program control unit 14. The digital logic computation process for CPU 10 is synchronously executed and driven by a set of pre-written sequential instructions stored in the instruction memory unit.

In digital computer systems based on the Von Neumann computing architecture numbers are represented in the binary formats. For example, an integer number/in the m-bit binary format is given by

$$I = {b}_{m - 1} {2}^{m - 1} + {b}_{m - 2} {2}^{m - 2} + … + {b}_{1} {2}^{1} + {b}_{0} = ( {b}_{m - 1} {b}_{m - 2} … {b}_{1} {b}_{0} ) b .$$

where bᵢ=[0, 1] for i=0, . . . , (m−1), and the symbol “b” indicates the integer number for the binary format.

The arithmetic operations such as multiplication, addition, subtraction, and division for binary numbers require manipulating the binary codes of operands to obtain the correct binary representation of the resultant numbers from the arithmetic operations in the circuit processors. The manipulations of the operant binary codes include feeding the binary codes into the combinational logic gates and placing the binary codes in the correct positions of the registers and memory units in IC processor chips. Therefore, the more manipulation steps of moving the binary codes in and out of various memory units, registers, and combinational gate logic units through their connecting bus-lines, the more computing power is consumed.

Specially, when a computing processor is operated with the individual bit-level manipulations of the code strings, the power consumption from charging and discharging the associated capacitances of the connecting bus-lines, the logic gates, the registers, and the memory units will significantly increase with the increasing operational steps as the power P ˜f×C×V_{DD}², where f is the step cycles for the processing time periods, C is the total charging/discharging associated capacitances required for the entire computation process, and V_{DD} is the high voltage supply. For example, the multiplication of two integer numbers represented by two n-bit binary codes is usually done by the so-called Multiply-Accumulation (MA) sequence: applying each single-bit of one “n-bit” operand for the bit-to-bit multiply (bit result obtained by the circuit “AND” gate) with every bit of another “n-bit” operand to obtain the number “n” of “n-bit” binary codes stored in registers; shifting each “n-bit” binary code in circuit to the correct positions in the “n” rows of 2n-bit long register; filling the empty bit registers with zeros for each row of the 2n-bit long registers; performing “(n−1)” steps of addition operations in binary addition circuits for the “n” number of 2n-bit long code strings in the registers to obtain the multiplication 2n-bit long binary code string. The computational power in processors is thus increased by the tedious steps of bit-level manipulations mainly from the transportation of intermediate data and instruction codes on a fixed bandwidth of bus-lines (currently with 8 bit, 16 bit, 32 bit, 64 bit formats) in processors. More steps of computing operations also indicate that higher frequency data transportation for intermediate data codes and additional instruction codes on the fixed bandwidth of bus-lines in processors is required. The heavy data and instruction code traffics for moving in and out of the memory units, logic gates, and registers specially in the computing pipeline processing may cause the bus-line congestion in the processors. The so-called Von Neumann bottleneck caused by the bus-line congestion of heavy data traffics between processor units and memory units is the main reason for slowing down computation processes.

From software programming prospective, the desirable one-step operation (completed in single clock cycle) shall simplify the computational algorithms and programming instructions for processors. Furthermore, the one-step multiplication operation could also save the required memory space for storing intermediary data and additional instruction codes resulting in chip memory area reduction in IC processor chip.

In the U.S. Pat. No. 11,461,074 B2 (the disclosure of which is incorporated herein by reference in its entirety), the binary multiple-digit in-memory multiplication devices comprising memory arrays for storing the base-2ⁿ multiplication table can reduce the numbers of intermediate operational steps for the multiplication of two binary integer operands. The one-step multiplication operation for two binary integer operands can be eventually achieved with the binary multiple-digit in-memory multiplication devices. In this invention, we further construct a binary floating-point in-memory multiplication device for two binary floating-point number operands.

Specially, the binary multiple-digit in-memory multiplication devices in the previous patent (U.S. Pat. No. 11,461,074 B2) is applied for the significand multiply in the binary floating-point in-memory multiplication device of the invention. Two floating-point decoders, and an exponent adder circuit are also incorporated in the floating-point in-memory multiplication device of the invention to achieve the one-step floating-point multiplication operation. For saving the computational power and boosting the computation efficiency, the binary floating-point in-memory multiplication device of the invention is designed to achieve one-step floating-point multiplication operation (completed in one clock cycle) such that the multiple times of data transportation between the multiplier unit, temporal data storage, and memory units in the conventional circuit processor can be totally omitted.

### SUMMARY OF THE INVENTION

According to IEEE 754 binary floating-point number format code, a binary floating-point number A is represented by one sign bit sa, a q-bit exponent ea, and a p-bit significand a, that is,

$$A = {( - )}^{s a} {2}^{e a} ( {a}_{p - 1} + {a}_{p - 2} \frac{1}{{2}^{1}} + … + {a}_{1} \frac{1}{{2}^{p - 2}} + {a}_{0} \frac{1}{{2}^{p - 1}} ) ≡ ( sa , {ea}_{q - 1} , {ea}_{q - 2} , … , {ea}_{1} , {ea}_{0} , {a}_{p - 1} , {a}_{p - 2} , … , {a}_{1} , {a}_{0} ) f ,$$

$$with$$

$$ea = ( e {a}_{q - 1} {2}^{q - 1} + e {a}_{q - 2} {2}^{q - 2} + … + e {a}_{1} {2}^{1} + e {a}_{0} {2}^{0} ) - {2}^{q - 1} + 1 ,$$

$$and$$

$$a = {a}_{p - 1} + {a}_{p - 2} \frac{1}{{2}^{1}} + … + {a}_{1} \frac{1}{{2}^{p - 2}} + {a}_{0} \frac{1}{{2}^{p - 1}} ,$$

where the binary numbers sa, eaᵢ, aⱼ=[0, 1] for i=0, . . . , (q−1) and j=0, . . . , (p−1), and f indicates the floating-point format.

Note that since the binary values of aₚ₋₁=0 for all eaᵢ=0 representing the sub-normal floating-point numbers and aₚ₋₁=1 for any non-zero eaᵢ representing the normal floating-point numbers can be decoded from the exponent bits eaᵢ for i=0, . . . , (q−1), a floating-point number code is usually stored and transported without the most significant bit (MSB) aₚ₋₁ of the significand. Therefore, the total number of bits stored and transported still remains (p+q) bits for the floating-point number code. For example, in computer systems, the floating point 8 is (p+q)=8 bits, the half precision is (p+q)=16 bits, the single precision is (p+q)=32 bits, the double precision is (p+q)=64 bits, the quadruple precision is (p+q)=128 bits, and the octuple precision is (p+q)=256 bits, and so forth. Floating-point decoders in the computing hardware are always to decode the binary value of the most significant bit aₚ₋₁ for the p-bit significand from the exponent bits (ea₀, . . . , ea_{q-1})b prior to binary arithmetic operations.

For the same format as the floating-point number A, a floating-point number B with one sign bit sb, a q-bit exponent bits eb, and a p-bit significand b is given by

$$B = {( - )}^{s b} {2}^{e b} ( {b}_{p - 1} + {b}_{p - 2} \frac{1}{{2}^{1}} + … + {b}_{1} \frac{1}{{2}^{p - 2}} + {b}_{0} \frac{1}{{2}^{p - 1}} ) ≡ ( sb , {eb}_{q - 1} , … , e {b}_{0} , {b}_{p - 1} {b}_{p - 2} , … , {b}_{1} , {b}_{0} ) f ,$$

$$with$$

$$eb = ( e {b}_{q - 1} {2}^{q - 1} + e {b}_{q - 2} {2}^{q - 2} + … + e {b}_{1} {2}^{1} + e {b}_{0} {2}^{0} ) - {2}^{q - 1} + 1 ,$$

$$and$$

$$b = {b}_{p - 1} + {b}_{p - 2} \frac{1}{{2}^{1}} + … + {b}_{1} \frac{1}{{2}^{p - 2}} + {b}_{0} \frac{1}{{2}^{p - 1}} ,$$

where the binary numbers sb, ebᵢ, bⱼ=[0, 1] for i=0, . . . , (q−1) and j=0, . . . , (p−1), and f indicates the floating-point format. Accordingly, the floating-point number M for the multiplication of A and Bis then given by

$$M = A * B = {( - )}^{s a + s b} {2}^{e a + e b} \frac{1}{{2}^{2 p - 2}} ( {a}_{p - 1} {2}^{p - 1} + {a}_{p - 2} {2}^{p - 2} + … + {a}_{1} {2}^{1} + {a}_{0} {2}^{0} ) ( {b}_{p - 1} {2}^{p - 1} + {b}_{p - 2} {2}^{p - 2} + … + {b}_{1} {2}^{1} + {b}_{0} {2}^{0} ) ,$$

$$and$$

$$M = {( - )}^{s m} {2}^{e m} \frac{1}{{2}^{2 p - 2}} ( {m}_{2 p - 1} {2}^{2 p - 1} + … + {m}_{p} {2}^{p} + {m}_{p - 1} {2}^{p - 1} + … + {m}_{0} {2}^{0} )$$

By comparing the above two equations for M, we obtain that sm=(sa+sb) for the “sign” of M, em=(ea+eb) for the “exponent” of M and the binary multiplication of the two p-bit significands of A and B, that is,

$$( {m}_{2 p - 1} , … , {m}_{p} , {m}_{p - 1} , … , {m}_{0} ) b = ( {a}_{p - 1} , {a}_{p - 2} , … , {a}_{1} , {a}_{0} ) b \times ( {b}_{p - 1} , {b}_{p - 2} , … , {b}_{1} , {b}_{0} ) b$$

According to the above equations for the “signs”, the “exponents”, and the “significands” of the floating-point number multiplication for two floating-point number operands, the schematic of a binary floating-point in-memory multiplication device 20 is designed to achieve the one-step floating-point multiplication operation as shown in FIG. 2. In FIG. 2, the voltage signals of two floating-point numbers A=(sa, ea_{q-1}, . . . , ea₀, aₚ₋₂, . . . , a₀) and B=(sb, eb_{q-1}, . . . eb₀, bₚ₋₂, . . . , b₀) are inputted from the A data register 21 and B data register 22 to a “sign” multiplication circuit 200 through the “sign” nodes 217 and 227, an “exponent” adder circuit 240 through the “exponent” nodes 218 and 228, and a binary in-memory multiplier circuit 250 through the “binary multiply” nodes 219 and 229 along with the outputs of a FP (Floating Point) decoder 210a and a FP decoder 210b respectively for the voltage signals of aₚ₋₁ and bₚ₋₁. The output voltage signals from an “exponent” adder circuit 240 and the in-memory multiplier circuit 250 are consequentially sent to the FP encoder circuit 270 for converting the resultant code back into the standard IEEE 754 floating-point number format code. The voltage signals of a FP encoder circuit 270 at the connection nodes 271 (i.e., nodes 271e for the exponent bits and nodes 271s for the significand bits) along with the “sign” voltage signals at the output node 201 of the “sign” multiplication circuit 200 are stored in the (p+q)-bit output register R 23. Note that the registers 220, 230, and 260 exist in the circuit device 20 only for the purpose of illustrating the voltage signals of intermediate data between the connection nodes. Those registers can be omitted in a real circuit implementation.

The floating-point in-memory multiplication device 20 of the invention performs one-step floating-point multiplication operation for two binary floating-point numbers without intermediate data storage and transportation between ALU, registers, and memory units, so the power consumption can be dramatically reduced. The invention performs one-step floating-point multiplication in memory units (i.e., through in-memory processing/computing), without moving intermediate data in/out of memory units, so as to avoid occupations of bus-line hardware (that may cause bus-line congestion or the Von Neumann bottle-neck in computers), to improve computation efficiency and to save computation power and time. The invention improves the field of in-memory processing/computing by using ROM arrays for storing the n-bit by n-bit multiplication tables (FIGS. 7-8) and transforming an identified leading non-zero bit position z into a binary format and by using specific adders for manipulating the output data from the multiplication tables and the q-bit exponents of both the multiplicand and the multiplier. In particular, no matter what precision the computer system is, the ROM array sizes for the n-bit by n-bit multiplication tables still remain reasonably small resulting in properly small silicon areas and high enough processing speeds.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows the conventional Von Neumann computing architecture for a typical Central Processing Unit (CPU).

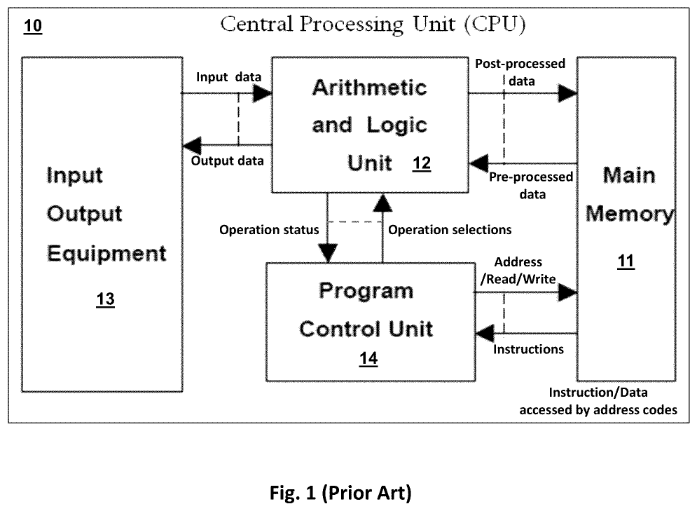

FIG. 2 shows a schematic diagram of a binary floating-point in-memory multiplication device 20 for two binary floating-point number multiplications according to the invention.

FIG. 3 shows a schematic diagram of “sign” multiplication circuit 200 for the sign operation of two floating-point number multiplications according to an embodiment.

FIGS. 4a and 4b respectively show the schematic diagrams of floating-point decoders 210a and 210b for generating the MSB of the significand from the exponent bits for a floating-point number.

FIG. 5 shows the schematic of a carry-chained exponent adder circuit 240 for the addition of the two exponent bits for the two floating-point number operands.

FIG. 6 shows the schematic of Perpetual Digital Perceptron (PDP) base-2ⁿ in-memory multiplier unit 600 for outputting the product codes of two n-bit long inputted codes based on the n-bit-by-n-bit multiplication table in FIG. 7.

FIG. 7 shows the 2n-bit binary product codes of the multiplication tables stored in PDP base-2ⁿ in-memory multiplier unit 600 for two n-bit long inputted binary operands.

FIG. 8 shows the 8-bit binary product codes of the multiplication tables stored in PDP base-2ⁿ in-memory multiplier unit 600 for two 4-bit (n=4) inputted binary operands in one embodiment of single precision floating-point number multiplication.

FIG. 9 shows the schematic of 6-digit base-2⁴ in-memory binary multiplier circuit 250A for the significand bit multiplication of two floating-point number operands in the embodiment of single precision floating-point number multiplication.

FIG. 10 shows the schematic of a carry-chained Binary Adder BA 920(j) in FIG. 9 to generate the “j^{th}” polynomial binary code (7-digit by 4-bit) for j=0, 1, 2, 3, 4, 5, in the embodiment of single precision floating-point number multiplication.

FIG. 11 shows the schematic of Polynomial Binary Adders PBA 930(i) in a carry-chained configuration in FIG. 9 to add up the six polynomial binary codes for i=0, 1, 2, 3, 4, in the embodiment of single precision floating-point number multiplication.

FIG. 12 shows the block schematic of floating-point encoder circuit 270 to convert the float-point multiplied number back into the standard IEEE 754 format for following data operations according to the invention.

FIG. 13 shows the block schematic of floating-point encoder circuit 270A to convert the float-point multiplied number back into the standard IEEE 754 format in the embodiment of single precision floating-point number multiplication.

FIG. 14 shows an example of the code table for different numbers z of left-shifted bit positions for the 24-bit significands in the embodiment of single precision floating-point number multiplication.

FIG. 15 shows the schematic of a barrel shifter 1340 in the embodiment of single precision floating-point number multiplication.

FIG. 16 shows the schematic of an addition/subtraction circuit 1330 in the embodiment of single precision floating-point number multiplication.

### DETAILED DESCRIPTION OF THE INVENTION

The following detailed description is meant to be illustrative only and not limiting. It is to be understood that other embodiment may be utilized and element changes may be made without departing from the scope of the present invention. Also, it is to be understood that the phraseology and terminology used herein are for the purpose of description and should not be regarded as limiting. Those of ordinary skill in the art will immediately realize that the embodiment of the present invention described herein in the context of methods and schematics are illustrative only and are not intended to be in any way limiting. Other embodiment of the present invention will readily suggest themselves to such skilled persons having the benefits of this disclosure.

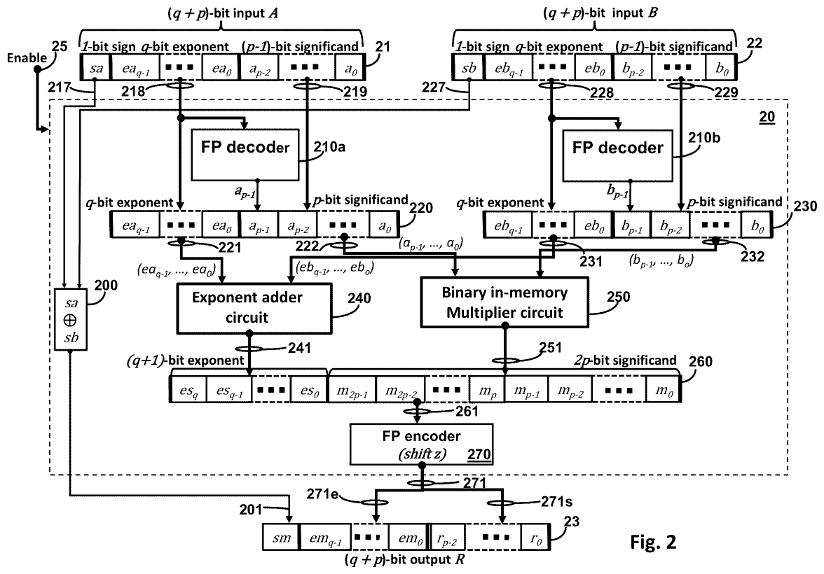

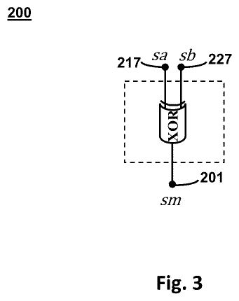

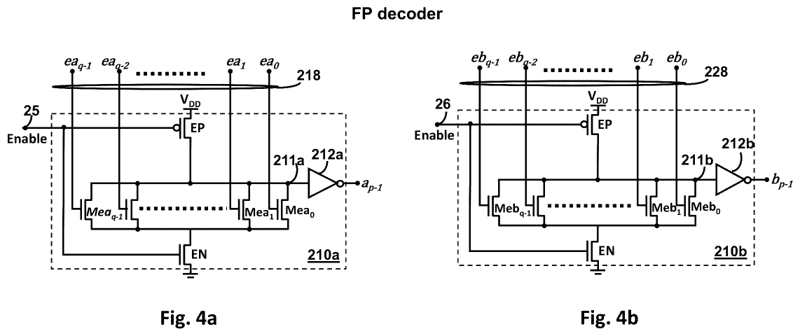

In the embodiment of the binary floating-point in-memory multiplication circuit device 20 in FIG. 2, the “sign” multiplication circuit 200 applies an XOR (exclusive OR) gate circuit for the voltage signals at nodes 217, 227, and 201 shown in FIG. 3 according to the logic operations of (sa=0, sb=0, and sm=0), (sa=0, sb=1, and sm=1), (sa=1, sb=0, and sm=1), and (sa=1, sb=1, and sm=0). The schematics of two FP decoder circuitries 210a and 210b for obtaining the voltage signals of the digital values of aₚ₋₁ and bₚ₋₁ for two p-bit significands are shown in FIGS. 4a and 4b. The FP decoder circuit 210a in FIG. 4a having the same circuit configuration as the circuit 210b in FIG. 4b comprises one P-type MOSFET (Metal Oxide Semiconductor Field Effect Transistor) devices EP, one N-type MOSFET device EN for the “enabled” operation, “q” N-type MOSFET devices (Mea_{q-1}, . . . , Mea₁, Mea₀) with their gates connected to the nodes (ea_{q-1}, . . . , eaᵢ, ea₀) 218, and an inverter 212a. When the circuit 210a is not enabled with low logic voltage signal “V_{SS}” at node 25, the EP device is turned on to charge the high logic voltage “V_{DD}” at the node 211a with the EN device off to disconnect from the ground voltage. While the circuit 210a is enabled with high logic voltage signal “V_{DD}” at node 25, the EP device is turned off to disconnect the node 211a from the high voltage “V_{DD}” and the EN device is turned on to cause the node 211a to connect to the ground voltage. While enabled, if any one of nodes (ea_{q-1}, . . . , ea₁, ea₀) 218 is applied with the high logic voltage signal “V_{DD}”, the correspondent N-type MOSFET device(s) of (Mea_{q-1}, . . . , Mea₁, Mea₀) will be turned on to discharge the node 211a to the ground voltage through the EN device such that the output aₚ₋₁ of the inverter 212a will flip to the high logic signal “V_{DD}” (logic value “1”). Otherwise, the output aₚ₋₁ will remain at low voltage signals “V_{SS}” (logic value “0”) resulting from the applied low gate voltage signals “V_{SS}” to the entire nodes of (ea_{q-1}, . . . , ea₁, ea₀) 218 shutting off all the N-type MOSFET devices of (Mea_{q-1}, . . . , Mea₁, Mea₀) to disconnect node 211a from the ground voltage. The circuit 210b for the floating-point number B works as the same way as the circuit 210a for the floating-point number A. The operations of the two FP decoder circuitries 210a and 210b are equivalent to q-input OR-gate devices. The above FP decoder circuitries 210a and 210b are utilized as embodiments and not limitations of the invention. In actual implementations, the above FP decoder circuitries 210a and 210b can be replaced with any other circuit layouts of q-input OR-gate devices or equivalent logic components.

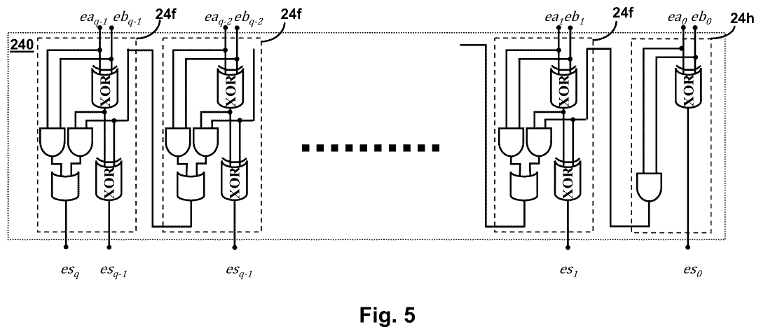

The addition for the two exponents (ea_{q-1}, . . . , ea₁, ea₀)b and (ea_{q-1}, . . . , ea₁, ea₀)b of the floating-point numbers A and B can be performed by a conventional carry-chained exponent adder circuit 240 comprising “q−1” full adders 24f (one OR gate, two XOR gates and two AND gates) and one half adder 24h (an “XOR” gate and an “AND” gate) for the Least Significant Bit (LSB) as shown in FIG. 5.

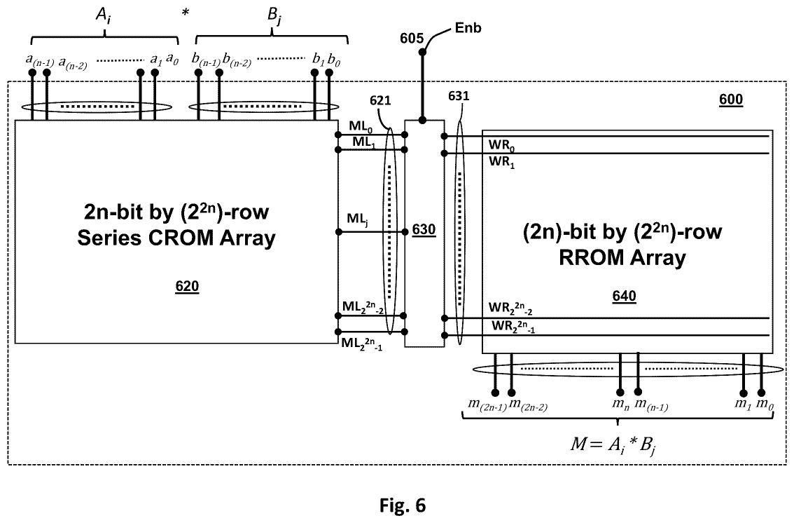

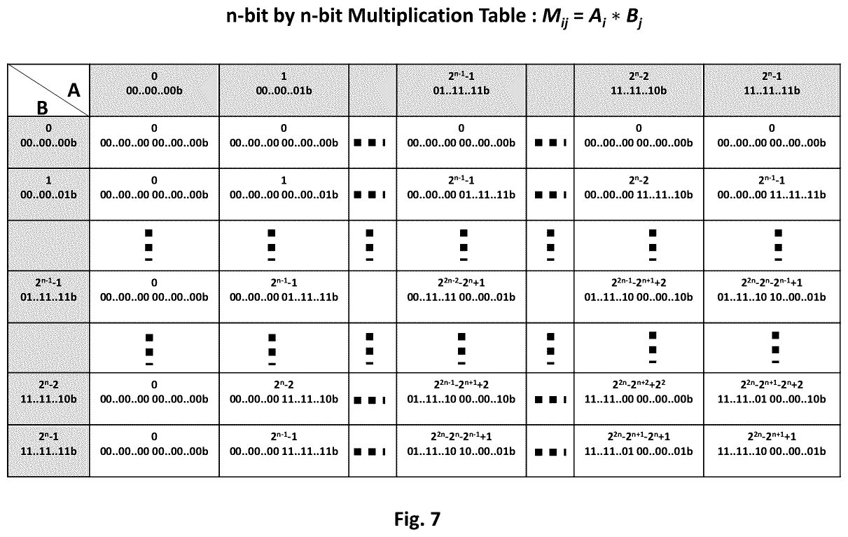

Referring to the disclosure of U.S. Pat. No. 11,461,074 B2, the binary multiple-digit base-2ⁿ in-memory multiplication devices comprising memory arrays for storing the base-2ⁿ multiplication table can reduce the numbers of intermediate operational steps for the multiplication of two p-bit binary operands. Therefore, the multiple-digit base-2ⁿ in-memory multiplication device with two operands each having the number (p/n) of digits can be designed for the binary significand multiplication. The p-bit by p-bit binary significand multiplication is converted to the (p/n)-digit by (p/n)-digit multiplication with each digit of each significand represented by a unique n-bit binary code. The (p/n)-digit by (p/n)-digit multiplication can be performed with (p/n)² digit-digit multiply and ((p/n)−1) polynomial additions. The voltage signals of multiplied/product binary code (2n-bit) for each digit-digit multiply are obtained from the output voltage signals of PDP base-2ⁿ in-memory multiplier unit 600 comprising a Content Read Only Memory (CROM) array 620, a match detector unit 630 and a Response Read Only memory (RROM) array 640 shown in FIG. 6. A number 2²ⁿ of 2n-bit operands Aᵢ and Bⱼ of multiplication table in FIG. 7 are hardwired in a number 2²ⁿ of rows of CROM cells (not shown) of the CROM array 620, where 0<=i, j<=((p/n)−1). A number 2²ⁿ of 2n-bit multiplication/product codes in the table cells of multiplication table in FIG. 7 are hardwired in a number 2²ⁿ of rows of RROM cells (not shown) of the RROM array 640. The match detector Unit 630 is enabled by the signal “Enb” at node 605 and configured to respectively sense the voltage potentials at the match-lines 621 for a matched match-line and then activate one of the wordlines 631 corresponding to the matched match-line. Basically, the PDP base-2ⁿ in-memory multiplier unit 600 functions as the following: compare the number 2²ⁿ of 2n-bit operand codes hardwired in the CROM array 620 with a first n-bit digit and a second n-bit digit respectively selected from the p-bit significand (aₚ₋₁, aₚ₋₂, . . . , a₀) in register 220 and the p-bit significand (bₚ₋₁, bₚ₋₂, . . . , b₀) in register 230; when one row of the 2n-bit operand code stored in the CROM array 620 is matched with the first n-bit digit and the second n-bit digit, the match detector Unit 630 activates the correspondent wordline in RROM 640 for the matched match-line to output one of the number 2²ⁿ of 2n-bit multiplication/product codes hardwired in the RROM 640 as a 2n-bit output code.

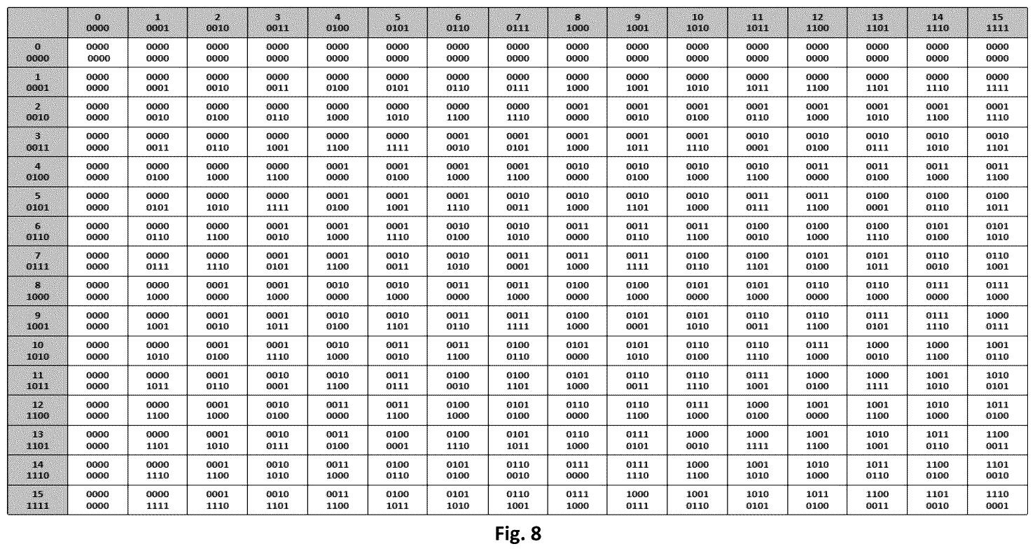

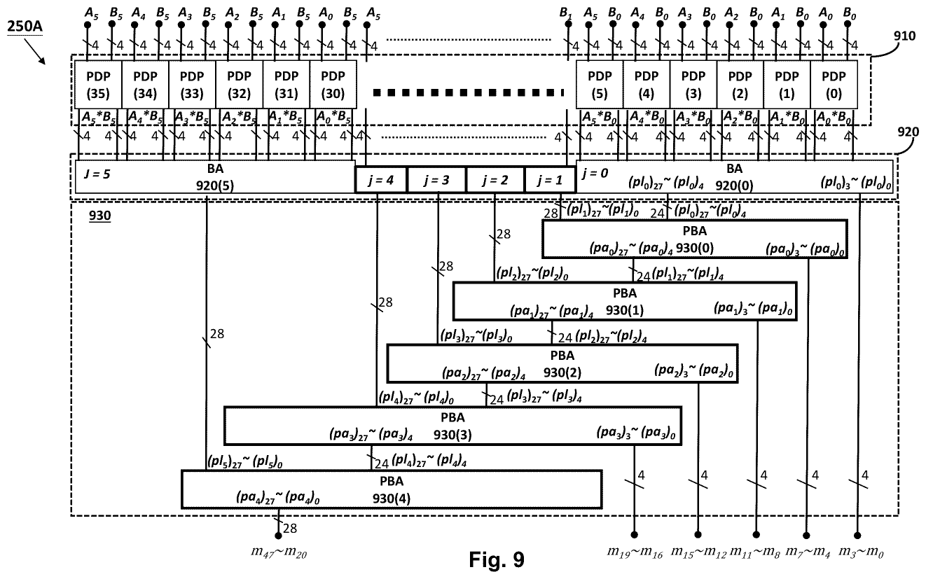

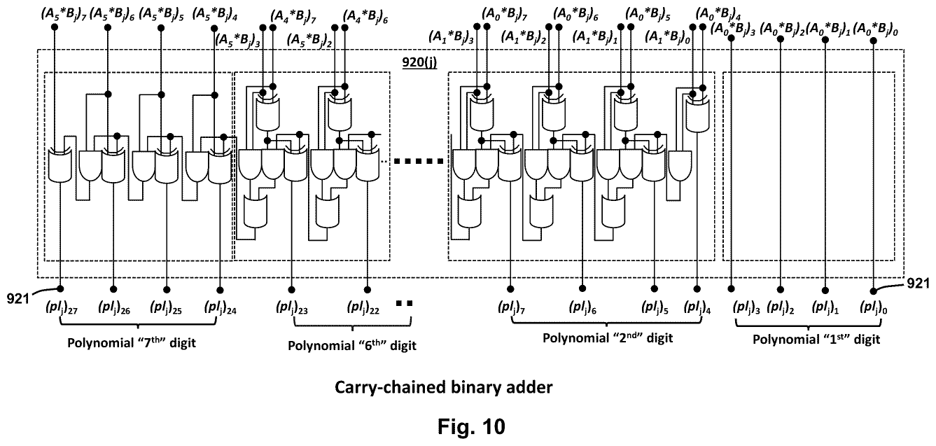

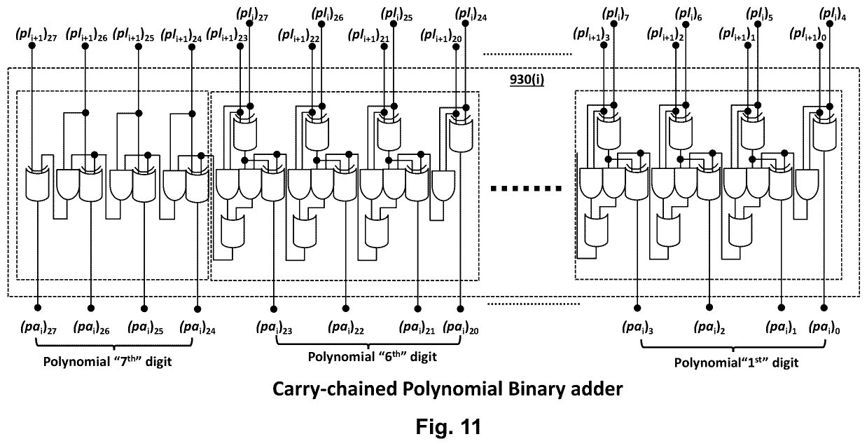

In one embodiment, the 32-bit single precision floating-point format (q=8 and p=24) comprises 24 bits for the significand. As shown in FIG. 9, we may apply the base-2⁴ (n=4 for the hexadecimal format) to represent a digit, so we then have 24/4=6 digits for the two 6-digit hexadecimal operand multiplication and finally obtain a 48-bit product code (m₄₇ . . . m₁m₀). The 6-digit base-2⁴ in-memory binary multiplier circuit 250A comprises thirty-six PDP base-2⁴ in-memory multiplier units 910(0)˜(35) (derived from PDP unit 600), six Binary Adders 920(0)˜(5) and five Polynomial Binary Adders 930(0)˜(4). The 6-digit by 6-digit multiplication is carried out by 36=6×6 digit-digit multiply with an array (910 in FIG. 9) of thirty-six PDP multiplier units each storing the 4-bit multiplication table shown in FIG. 8 for simultaneously parallel multiply, six carry-chained Binary Adders (BA 920(j) in FIG. 10) to generate six 7-digit polynomial binary codes and five carry-chained Polynomial Binary Adders (PBA 930(i) in FIG. 11) for five additions of the six 7-digit polynomial binary codes, for i=0˜4; j=0˜5. The Binary Adder (BA 920(j)) receives six 8-bit coefficients/binary codes of the polynomial (A₅*BⱼX^{5+j}+A₄*BⱼX^{4+j}+A₃*BⱼX^{3+j}+A₂*BⱼX^{2+j}+A₁*BⱼX^{1+j}+A₀*BⱼX^{0+j}) to generate the 7-digit 4-bit (4 bits×7) polynomial binary codes for j=0, . . . , 5, where X=2⁴. Each binary adder 920(j) comprises five 4-bit adders and four half adders in a carry-chained configuration. We illustrate the output nodes 921 of BA circuitry 920(j) in FIG. 10 as the following: the 4-bit binary code for the first digit (Least Significant Digit) of the output of each BA 920(j) is directly passed from the PDP unit 910(0+6*j) producing the least significant 4-bit binary code of (A₀*Bⱼ). The 20-bit binary code for the middle digits (2^{nd} digit to 6^{th} digit) of the output of each BA 920(j) is then obtained by the binary addition of the least significant four bits of (Aₖ₊₁*Bⱼ) and the most significant four bits of (Aₖ*Bⱼ) for k=0, 1, 2, 3, 4. The 4-bit binary code for the 7^{th} digit of the output of each BA 920(j) is obtained by adding the carry-bit from the 6th digit to the most significant four bits of (A₅*Bⱼ). In brief, the operation of a first binary adder BA 920(0) is equivalent to converting 8-bit first coefficients of a first polynomial of degree 5 (i.e., A₅*B₀X₅+A₄*B₀X₄+A₃*B₀X₃+A₂*B₀X₂+A₁*B₀X₁+A₀*B₀X⁰) into 4-bit second coefficients of a second polynomial of degree 6 (i.e., C₆X⁶+C₅X⁵+C₄X⁴+C₃X³+C₂X²+C₁X¹+C₀X⁰) in mathematics; the operation of a second binary adder BA 920(1) is equivalent to converting 8-bit first coefficients of a first polynomial of degree 6 (i.e., A₅*B₁X⁶+A₄*B₁X⁵+A₃*B₁X⁴+A₂*B₁X³+A₁*B₁X²+A₀*B₁X¹) into 4-bit second coefficients of a second polynomial of degree 7 (i.e., C₁₃X⁷+C₁₂X⁶+C₁₁X⁵+C₁₀X⁴+C₉X³+C₈X²+C₇X¹) in mathematics; . . . ; the operation of a sixth binary adder BA(5) is equivalent to converting 8-bit first coefficients of a first polynomial of degree 10 (A₅*B₅X¹⁰+A₄*B₅X⁹+A₃*B₅X⁸+A₂*B₅X⁷+A₁*B₅X⁶+A₀*B₅X⁵) into 4-bit second coefficients of a second polynomial of degree 11 (C₄₁X¹¹+C₄₀X¹⁰+C₃₉X⁹+C₃₈X⁸+C₃₇X⁷+C₃₆X⁶+C₃₅X⁵) in mathematics, where X=2⁴. A total of six 7-digit polynomial codes (i.e., a total of forty-two 4-bit second coefficients C₀˜C₄₁) are simultaneously generated by six binary adders BA 920(0)˜(5) for the following polynomial additions.

The schematic of PBA 930(i) in a carry-chained configuration for i=0, 1, 2, 3, 4 is shown in FIG. 11. Each polynomial binary adder 930(i) comprises a (6×4)-bit adder and four half adders in a carry-chained configuration. The output nodes for the most significant 24 bits of the “0^{th}” 7-digit polynomial code (from BA 920(0)) and the output nodes for the 28-bits of the “1^{st}” 7-digit polynomial code (from BA 920(1)) are respectively connected to the input nodes ((pIᵢ)₂₇(pIᵢ)₂₆ . . . (pIᵢ)₄) and ((pIᵢ₊₁)₂₇(pIᵢ₊₁)₂₆ . . . (pIᵢ₊₁)₁(pIᵢ₊₁)₀) of the PBA 930(0) shown in FIG. 11, for i=0; the output nodes for the most significant 24 bits of the 7-digit polynomial code (from PBA 930(i−1)) and the output nodes for the 28-bits of the “(i+1)^{th}” 7-digit polynomial code (from BA 920(i+1)) are respectively connected to the input nodes ((pIᵢ)₂₇(pIᵢ)₂₆ . . . (pIᵢ)₄) and ((pIᵢ₊₁)₂₇(pIᵢ₊₁)₂₆ . . . (pIᵢ₊₁)₁(pIᵢ₊₁)₀) of the PBA 930(i) shown in FIG. 11, for i=1˜4. PBA 930(i) outputs the voltage signals at the output nodes, ((paᵢ)₂₇(paᵢ)₂₆ . . . (paᵢ)₁(paᵢ)₀) for the “i^{th}” polynomial addition. In FIG. 9, the voltage signals of multiplication of two significands at the nodes (m₄₇m₄₆ . . . m₁m₀) consist of the voltage signals of the most significant 28-bits at the output nodes (m₄₇˜m₂₀) of PBA 930(4), and the voltage signals of the least significant 20 bits respectively from the least significant 4-bit output nodes (m₁₉˜m₁₆) of PBA 930(3), the least significant 4-bit output nodes (m₁₅˜m₁₂) of PBA 930(2), the least significant 4-bit output nodes (m₁₁˜m₈) of PBA 930(1), and the least significant 4-bit output nodes (m₇˜m₄) of PBA 930(0) along with the least significant 4-bit output node (m₃˜m₀) of BA 920(0) as shown in FIG. 9. The operations of the PBA 930(0)˜(4) are equivalent to lining up and adding like terms of the above second polynomials of degrees ranging from 6 to 11 to obtain 4-bit third coefficients of a third polynomial of degree 11 in mathematics. Here, the third polynomial has twelve terms.

For transforming the floating-point number format of the multiplied binary result from the binary in-memory multiplier circuit 250, the floating-point number M in the form of a 2p-bit significand is written by

$$M = {( - )}^{s m} {2}^{e m + 1} ( {m}_{2 p - 1} + … + {m}_{p} \frac{1}{{2}^{p - 1}} + {m}_{p - 1} \frac{1}{{2}^{p}} + … + {m}_{0} \frac{1}{{2}^{2 p - 1}} ) ,$$

$$and$$

$$em + 1 = e a + e b + 1 = ( e {a}_{q - 1} {2}^{q - 1} + … + e {a}_{0} {2}^{0} ) - {2}^{q - 1} + 1 + ( {eb}_{q - 1} {2}^{q - 1} + … + e {b}_{0} {2}^{0} ) - {2}^{q - 1} + 1 + 1 = ( e {a}_{q - 1} + e {b}_{q - 1} - 1 ) {2}^{q - 1} + ( e {a}_{q - 2} + e {b}_{q - 2} ) {2}^{q - 2} + … + ( e {a}_{1} + e {b}_{1} + 1 ) {2}^{1} + ( e {a}_{0} + e {b}_{0} ) {2}^{0} - {2}^{q - 1} + 1 .$$

In term of (q+1)-bit binary format, the exponent em is given by

$$( e {m}_{q} e {m}_{q - 1} e {m}_{q - 2} … {em}_{1} e {m}_{0} ) b = ( 0 e {a}_{q - 1} e {a}_{q - 2} … {ea}_{1} e {a}_{0} ) b + ( 0 e {b}_{q - 1} e {b}_{q - 2} … {eb}_{1} e {b}_{0} ) b + ( 00 … 10 ) b - ( 01 … 00 ) b = ( {es}_{q} e {s}_{q - 1} … {es}_{1} e {s}_{0} ) b + ( 00 … 10 ) b - ( 01 … 00 ) b ,$$

where (em_{q}em_{q-1} . . . em₁em₀)b is the result of the binary addition/subtraction of the above equation, and (es_{q}es_{q-1} . . . es₁es₀)b is the result of the binary addition of (ea_{q-1}ea_{q-2} . . . ea₁ea₀)b and (eb_{q-1}eb_{q-2} . . . eb₁eb₀)b from the previous exponent adder circuit block 240 in FIG. 2.

Meanwhile according to the IEEE 754 floating-point number format, the significands (m₂ₚ₋₁ . . . mₚmₚ₋₁ . . . m₀)b must be left-shifted to obtain the first leading non-zero bit until the exponent bits (em_{q-1}em_{q-2} . . . em₁em₀)b all become zeros for the subnormal floating-point numbers (that is, the number of left-shifted bit positions equal to the maximum value “p”). We denote the number of left-shifted bit positions (i.e., a shift distance relative to the MSB m₂ₚ₋₁) to be z and z=zₜ₋₁2^{t-1}+ . . . +z₀2⁰:=(0 . . . zₜ₋₁ . . . z₀)b in the (q+1)-bit binary format, where 0<=z<=(p−1) and t=roundup (log₂p). Therefore, the final exponent bits in the (q+1)-bit format is given by

$$( e {m}_{q} e {m}_{q - 1} e {m}_{q - 2} … {em}_{1} e {m}_{0} ) b = ( e {s}_{q} e {s}_{q - 1} … {es}_{1} e {s}_{0} ) b + ( 00 … 10 ) b - ( 01 … {z}_{t - 1} … {z}_{0} ) b$$

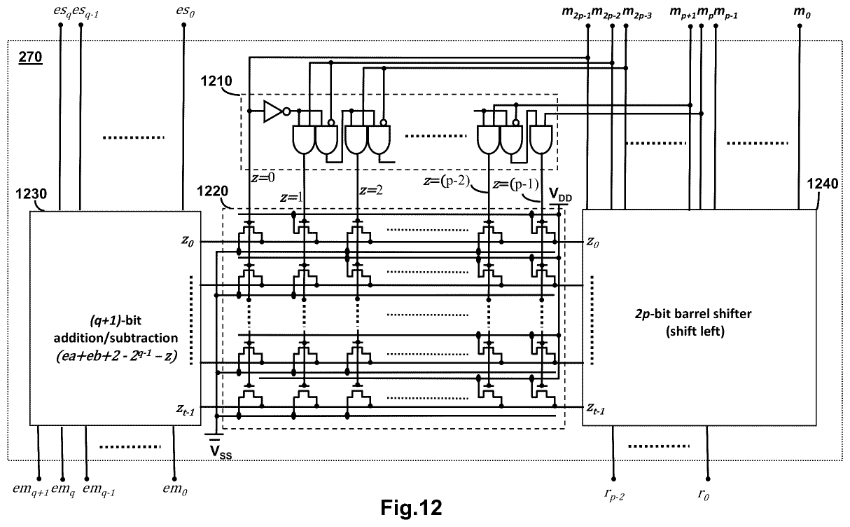

The schematic of the floating-point encoder circuit 270 is shown in FIG. 12. In FIG. 12, the exponent voltage signals at the input nodes (es_{q}es_{q-1} . . . es₁es₀) of addition/subtraction circuit block 1230 are received for the binary additions/subtraction for the number equation of (ea+eb+2−2^{q-1}−z). Meanwhile the multiplication voltage signals at the nodes (m₂ₚ₋₁ . . . mₚmₚ₋₁ . . . m₀) are simultaneously sent to both Lead Zero Detector (LZD) 1210 for detecting the first non-zero bit among the most significant p bits of the 2p-bit product from the circuit 250 and the barrel shifter 1240 for shifting the 2p-bit significand. Starting from the MSB m₂ₚ₋₁, the LZD 1210 detects the first non-zero bit among the most significant p bits of the 2p-bit product to turn on the correspondent word-line in the position shifting encoder 1220 to output the voltage signals of the binary code for the number z of left-shifted bit positions. For example, in FIG. 12, if m₂ₚ₋₁=“1” with voltage signal V_{DD}, the LZD circuitry 1210 will turn on the first column word-line of the position shifting encoder 1220 to output the voltage signals of the binary code (0 . . . 0)b both for the 2p-bit barrel shifter 1240 to shift the 2p-bit product (m₂ₚ₋₁ . . . mₚmₚ₋₁ . . . m₀)b from the circuit 250 to the left by zero bit position (z=0) and the addition/subtraction circuit block 1230 for the binary additions/subtraction for the number equation. If m₂ₚ₋₁=“0” with voltage signal V_{SS} and m₂ₚ₋₂=“1” with voltage signal V_{DD}, the LZD circuitry 1210 will turn on the second column word-line of ROM array 1220 to output the voltage signals of binary code (0 . . . 1)b both for the 2p-bit barrel shifter 1240 to shift the 2p-bit product to the left by one bit position (z=1) and the addition/subtraction circuit block 1230 for the binary additions/subtraction for the number equation. Basically, the position shifting encoder 1220 receives the voltage signals from the LZD circuitry 1210 to convert the number z of left-shifted bit positions into a binary code representation. The exponent voltage signals of the addition/subtraction circuit block 1230 at the output nodes (em_{q-1}em_{q-2} . . . em₁em₀) and the significand voltage signals of barrel shifter 1240 at the output nodes (rₚ₋₂ . . . r₁r₀) form the voltage signals of a floating-point multiplication number code complied with the IEEE 754 floating-point standard format. Note that the exponent voltage signals for em_{q+1} node and em_{q} node are used for the flag signals of underflow and overflow situations, respectively.

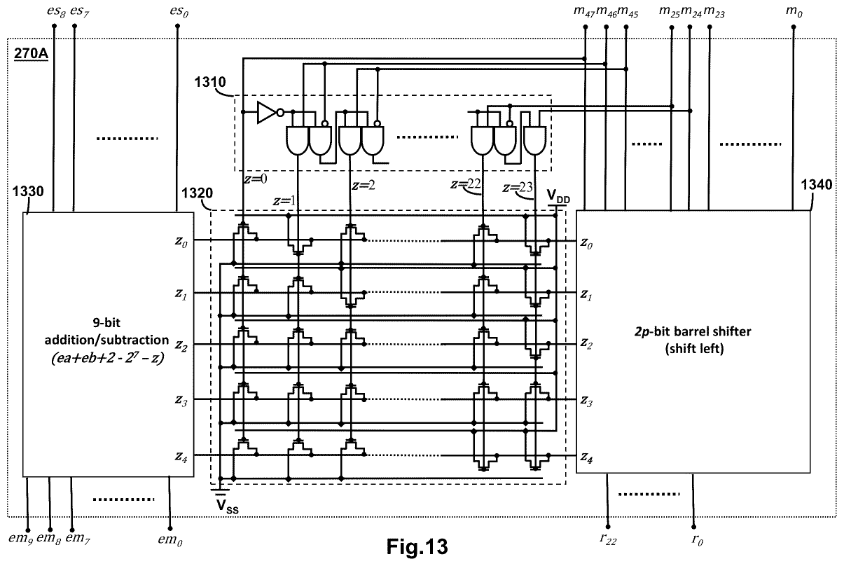

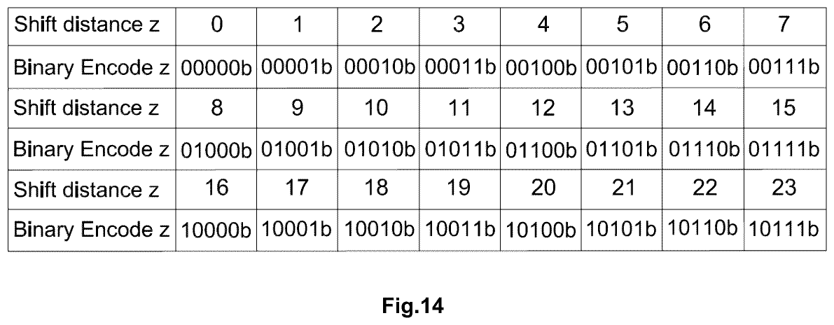

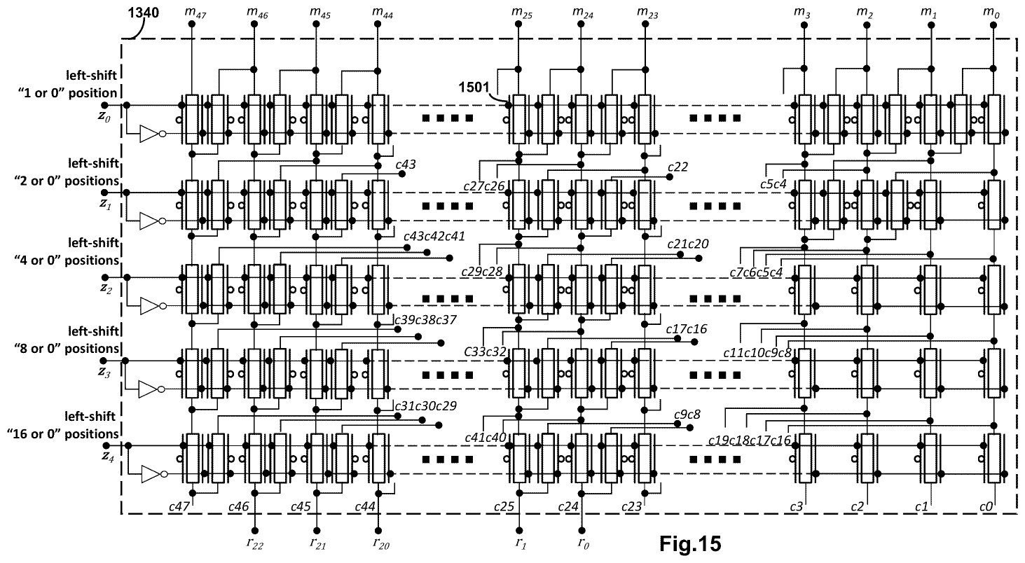

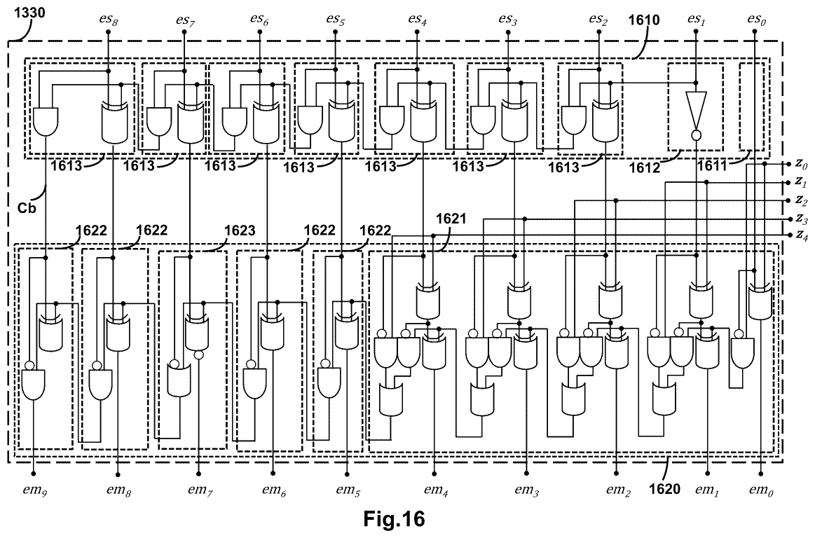

In one embodiment for the 32-bit single precision (q=8 and p=24) floating-point encoder 270A, the output nodes for the 48-bit multiplication significands (m₄₇ . . . m₂₄m₂₃ . . . m₀)b from the 6-digit base-2⁴ in-memory binary multiplier circuit 250A in FIG. 9 are connected to the input nodes of the barrel shifter 1340 along with the output nodes of the most significant 24 bits (m₄₇ . . . m₂₄)b connected to the input nodes of the LZD circuit 1310, and the 9-bit exponent (es₈es₇ . . . es₁es₀)b from the binary addition of (ea+eb) by the exponent adder circuit 240 are transmitted to the input nodes of addition/subtraction circuit 1330 shown in FIG. 13. The LZD circuit 1310 comprising multiple NAND gates detects the first leading non-zero bit relative to the MSB (m₄₇) among the most significant 24 bits (m₄₇ . . . m₂₄)b of the 48-bit multiplication significands. The LZD circuit 1310 outputs the voltage signal “V_{DD}” (logic value “1”) at the first leading non-zero bit position detected and voltage signal “V_{SS}” (logic value “0”) otherwise. The output voltage signals of LZD circuit 1310 are inputted into the position shifting encoder 1320. The position shifting encoder 1320 comprises a ROM array with the correspondent word-lines connected with the output nodes of LZD circuit 1310. The predefined binary codes stored in multiple ROM cells of the ROM array 1320 in advance for the number z of left-shifted bit positions are shown in FIG. 14, where z=z₄2⁴+z₃2³+z₂2²+z₁2¹+z₀2⁰ for (z₄z₃z₂z₁z₀)b. When the voltage signal “V_{DD}” at the output node of the first leading non-zero bit position is applied to the correspondent word-line in the ROM array 1320, the voltage signals of a predefined binary code z (=(z₄z₃z₂z₁z₀)b) at the bit-line nodes of the ROM array 1320 are simultaneously outputted to the input nodes of a barrel shifter 1340 in FIG. 15 and an addition/subtraction circuit 1330 in FIG. 16. FIG. 15 shows the schematic of 48-column left-shifting barrel shifter 1340 decoded by the 5-bit input code z (=(z₄z₃z₂z₁z₀)b) in binary format. The barrel shifter 1340 comprises an array of Transmission Gates (TGs) 1501 with the connections to left-shift the voltage signals from the input nodes (m₄₇m₄₆ . . . m₁m₀) to the output nodes (r₂₂r₂₁ . . . r₁r₀) by z bit positions. The connections for the left-shifted bit positions are configured as the followings: (z₄z₃z₂z₁z₀) are the control nodes for the correspondent rows of TGs to make the connections for left-shifting (16 columns or 0 column) by z₄, (8 columns or 0 column) by z₃, (4 columns or 0 column) by z₂, (2 columns or 0 column) by z₁, and (1 column or 0 column) z₀, respectively. Thus, there are a total of five multiplexing stages connected in cascaded. The voltage signal “V_{DD}” (logic value “1”) at any node of (z₄z₃z₂z₁z₀) is applied to turn on the correspondent row of the TG to pass the voltage signals from the connecting inputted nodes to the correspondent left-shifted column output nodes. While the voltage signal “V_{SS}” (logic value “0”) at the nodes of (z₄z₃z₂z₁z₀) is applied to turn on the correspondent row of TGs to pass the voltage signals from the connecting inputted nodes to the same column output nodes without any left shifting. The voltage signals at the output nodes (r₂₂r₂₁ . . . r₁r₀) of the barrel shifter 1340 represent the digit voltage signals for the (p−1)-bit significand of the single precision floating-point number complied with the standard IEEE 754 floating-point number code format (p=24).

Meanwhile, the schematic of addition/subtraction circuit (1330 in FIG. 13) for the embodiment of the 32-bit single precision floating-point encoder 270A is shown in FIG. 16. The binary addition circuitry 1610 comprises the logic gate circuit elements 1611, 1612, 1613 for the binary addition of (es₈es₇es₆es₅es₄es₃es₂es₁es₀)b+(000000010)b. The 10-bit output nodes (including the carry bit node Cb) of the addition circuitry 1610 are connected to the input nodes of the binary subtraction circuitry 1620 comprising the logic gate elements 1621, 1623, and 1622 for subtracting (00100z₄z₃z₂z₁z₀)b from the output value of the binary addition circuitry 1610. The voltage signals at the output nodes (em₇em₆em₅em₄em₃em₂em₁em₀) represent the digital voltage signals for the q-bit exponent (q=8) of the single precision floating-point number complied with the standard IEEE 754 floating-point number code format. The output voltage signals at the node em₉ and em₈ with the voltage signal “V_{DD}” (logic value “1”) indicate the “underflow and “overflow” situations, respectively for the single precision floating-point number.

Please note that the above barrel shifter 1240/1340, the exponent adder circuit 240, the binary addition circuitry 1610 and the subtraction circuitry 1620 are utilized as embodiments and not limitations of the invention. In actual implementations, the above barrel shifter 1240/1340 can be replaced with any other types of barrel shifter, such as a crossbar barrel shifter and a barrel shifter implemented as a cascade of parallel multiplexers; the exponent adder circuit 240 and the binary addition circuitry 1610 can be replaced with any other types of binary addition circuitry, such as Carry Save Adder and Look Ahead Adder; the subtraction circuitry 1620 can be replaced with any other types of binary subtraction circuitry; and these also fall in the scope of the invention. Please also note that the above CROM array 620, the RROM array 640 and the ROM arrays 1220/1320 are utilized as embodiments and not limitations of the invention. In actual implementations, the above CROM array 620, the RROM array 640 and the ROM arrays 1220/1320 can be replaced with any other types of memory arrays or equivalent logic components, and this also falls in the scope of the invention.

The aforementioned description of the preferred embodiment of the invention has been presented for purposes of illustration and description. It is not intended to be exhaustive or to limit the invention to the precise form or to exemplary embodiment disclosed. Accordingly, the description should be regarded as illustrative rather than restrictive. The embodiment is chosen and described in order to best explain the principles of the invention and its best mode practical application, thereby to enable persons skilled in the art to understand the invention for various embodiment and with various modifications as are suited to the particular use or implementation contemplated. It is intended that the scope of the invention be defined by the claims appended hereto and their equivalents in which all terms are meant in their broadest reasonable sense unless otherwise indicated. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiment of the invention. It should be appreciated that variations may be made in the embodiment described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A floating-point in-memory multiplication device for performing multiplication on a multiplicand and a multiplier and generating a first product, wherein each of the multiplicand, the multiplier and the first product is a binary floating-point number in IEEE 754 format and consists of a sign bit, a q-bit exponent and a (p−1)-bit significand, the device comprising:
a XOR gate device for receiving sign bits of the multiplicand and the multiplier to generate a sign bit of the first product;
a decoder circuit for generating a first prefix bit according to a q-bit exponent of the multiplicand and generating a second prefix bit according to a q-bit exponent of the multiplier, wherein the first prefix bit and the (p−1)-bit significand of the multiplicand form a first p-bit significand, and the second prefix bit and the (p−1)-bit significand of the multiplier form a second p-bit significand;
an exponent adder circuit for adding up the q-bit exponents of the multiplicand and the multiplier to generate a (q+1)-bit temporary exponent;
a binary in-memory multiplier circuit for performing multiplication on the first and the second p-bit significands to generate a 2p-bit second product; and
an encoder circuit for identifying and transforming a target bit position among the most significant p bits of the 2p-bit second product into a shift distance z, calculating a q-bit exponent of the first product according to the (q+1)-bit temporary exponent and a value of (2−2^{q-1}−z), and shifting the 2p-bit second product to the left by z bit positions to generate a (p−1)-bit significand of the first product;
wherein the target bit position contains a nonzero value and is closest to a most significant bit position of the 2p-bit second product, where 0<=z<=(p−1) and (p+q)>=8.

2. The device according to claim 1, wherein the decoder circuit comprises:
a first OR gate device for receiving binary bits of the q-bit exponent of the multiplicand to generate the first prefix bit; and
a second OR gate device for receiving binary bits of the q-bit exponent of the multiplier to generate the second prefix bit.

3. The device according to claim 1, wherein the exponent adder circuit is implemented by a carry-chained adder circuit comprising a number (q−1) of full adders and a half adder.

4. The device according to claim 1, wherein the encoder circuit comprises:
a detection circuit having p output terminals for identifying the target bit position relative to the most significant bit position of the 2p−bit second product to generate an activated bit and (p−1) de-activated bits at the p output terminals;
a first ROM array for receiving the activated bit and (p−1) de-activated bits to output the shift distance z in binary format;
a calculation circuit for adding the (q+1)-bit temporary exponent and a value of 2 to produce a (q+1)-bit sum, and for subtracting a value of (2^{q-1}+z) from the (q+1)-bit sum to obtain the q-bit exponent of the first product; and
a barrel shifter for shifting the 2p-bit second product to the left by the z bit positions to generate the (p−1)-bit significand of the first product.

5. The device according to claim 4, wherein the first ROM array comprises:
multiple ROM cells arranged in rows and columns configuration and storing multiple predefined binary codes in advance;
a number p of word lines respectively connected to the p output terminals of the detection circuit; and
a number t of bit lines coupled to the calculation circuit and the barrel shifter;
wherein when one of the number p of word lines is enabled by the activated bit, a corresponding row of ROM cells are turned on to output the shift distance z in t-bit binary format at the number t of bit lines, where t=roundup (log₂p).

6. The device according to claim 4, wherein the detection circuit
a number (p−2) of logic blocks connected in series, wherein the number (p−2) of logic blocks operate in a logic block order starting from a first logic block (1) and proceeding successively to each next logic block until a last logic block (p−2) is reached, wherein the first logic block (1) is enabled by an inversion of a most significant bit (MSB) of the 2p-bit second product and checks a (2p−2)^{th} bit of the 2p-bit second product to produce a control bit and provide a first datum for an output terminal (p−2) of the p output terminals, wherein a logic block (i) of the number (p−2) of logic blocks is enabled by a control bit from a preceding logic block (i−1) and checks a (2p−1−i)^{th} bit of the 2p-bit second product to produce a control bit and provide a second datum for an output terminal (p−1−i) of the p output terminals, where 2<=|<=(p−2); and
a logic component enabled by a control bit from the last logic block (p−2) and checking a p^{th} bit of the 2p-bit second product to provide a third datum for an output terminal (0) of the p output terminals;
wherein the MSB of the 2p-bit second product is provided for an output terminal (p−1) of the p output terminals, and data provided at the p output terminals form the activated bit and the (p−1) de-activated bits.

7. The device according to claim 6, wherein each of the number (p−2) of logic blocks comprises:
a first AND gate device having a first noninverted input, a second noninverted input and a first output, wherein the first output is coupled to the first ROM array; and
a second AND gate device having a third noninverted input, an inverted input and a second output;
wherein the second noninverted input and the inverted input for the logic block (i) receive a ((2p−1−i)^{th}) bit of the 2p-bit second product, and the first and third noninverted inputs for the logic block (i) are coupled to the second output of the preceding logic block (i−1).

8. The device according to claim 6, wherein the logic component is implemented by a third AND gate device.

9. The device according to claim 4, wherein the barrel shifter comprises 2p input terminals, 2p output terminals and t multiplexing stages connected in cascaded, wherein the 2p input terminals receive the 2p-bit second product and correspond to the 2p output terminals, wherein the t multiplexing stages are configured to shift the 2p-bit second product to the left by the z bit positions to produce a 2p-bit shifted product at the 2p output terminals, and wherein a p^{th} bit to a (2p−2)th bit of the 2p-bit shifted product at a number (p−1) of output terminals of the 2p output terminals are outputted as the (p−1)-bit significand of the first product, where t=roundup (log₂p).

10. The device according to claim 1, wherein the binary in-memory multiplier circuit comprises:
k² in-memory multiplier units arranged in a parallel configuration, each of the k² in-memory multiplier units comprising a second ROM array and a third ROM array and comparing a number 2²ⁿ of 2n-bit operand symbols hardwired in the second ROM array with a first n-bit digit and a second n-bit digit respectively selected from the first and the second p-bit significands to output one of a number 2²ⁿ of 2n-bit response symbols hardwired in the third ROM array as a 2n-bit product code, wherein all the 2n-bit product codes outputted from the k² in-memory multiplier units form 2n-bit first coefficients of k first polynomials in base 2ⁿ and the 2n-bit first coefficients of each first polynomial in base 2ⁿ are associated with multiplication of the first p-bit significand with a corresponding digit of the second p-bit significand, wherein each of the first and the second p-bit significands has k digits in base 2ⁿ and k=p/n;
k binary adder circuits arranged in a parallel configuration for converting the 2n-bit first coefficients of the k first polynomials in base 2ⁿ into n-bit second coefficients of k second polynomials in base 2ⁿ in parallel; and
a number (k−1) of polynomial adder circuits arranged in sequential order and sequentially adding the n-bit second coefficients of the k second polynomials in base 2ⁿ in ascending degrees such that like terms of the k second polynomials in base 2ⁿ are lined up and added to generate n-bit third coefficients of a third polynomial in base 2ⁿ, wherein the third coefficients form the 2p-bit second product, and k and n are integers greater than 0.

11. The device according to claim 10, wherein each of the k binary adder circuit comprises (k−1) n-bit adders and n half adders in a carry-chained configuration.

12. The device according to claim 10, wherein each of the number (k−1) of polynomial adder circuits comprises a (k×n)-bit adder and n half adders in a carry-chained configuration.

13. The device according to claim 10, wherein the number 2²ⁿ of 2n-bit operand symbols and the number 2²ⁿ of 2n-bit response symbols define an n-bit by n-bit multiplication table.

14. An operating method of a floating-point in-memory multiplication device that performs multiplication on a multiplicand and a multiplier to generate a first product, the floating-point in-memory multiplication device comprising a binary in-memory multiplier circuit and an encoder circuit, wherein each of the multiplicand, the multiplier and the first product is a binary floating-point number in IEEE 754 format and consists of a sign bit, a q-bit exponent and a (p−1)-bit significand, the method comprising the steps of:
performing a XOR operation over sign bits of the multiplicand and the multiplier to obtain a sign bit of the first product;
respectively obtaining a first prefix bit and a second prefix bit according to the q-bit exponent of the multiplicand and the q-bit exponent of the multiplier such that the first prefix bit and the (p−1)-bit significand of the multiplicand form a first p-bit significand, and the second prefix bit and the (p−1)-bit significand of the multiplier form a second p-bit significand;
adding up the q-bit exponent of the multiplicand and the q-bit exponent of the multiplier to obtain a (q+1)-bit temporary exponent;
performing multiplication on the first and the second p-bit significands by the binary in-memory multiplier circuit to obtain a 2p-bit second product;
identifying and transforming a target bit position among the most significant p bits of the 2p-bit second product into a shift distance x by the encoder circuit, wherein the target bit position contains a nonzero value and is closest to a most significant bit position of the 2p-bit second product;
calculating a q-bit exponent of the first product by the encoder circuit according to the (q+1)-bit temporary exponent and a value of (2−2^{q-1}−z); and
shifting the 2p-bit second product to the left by z bit positions by the encoder circuit to obtain a (p−1)-bit significand of the first product;
wherein 0<=z<=(p−1) and (p+q)>=8.

15. The method according to claim 14, wherein the step of obtaining the first prefix bit and the second prefix bit comprises:
performing an OR operation over binary bits of the q-bit exponent of the multiplicand to obtain the first prefix bit; and
performing an OR operation over binary bits of the q-bit exponent of the multiplier to obtain the second prefix bit.

16. The method according to claim 14, wherein the step of identifying and transforming comprises:
identifying the target bit position relative to the most significant bit position of the 2p-bit second product by a number (p−2) of logic blocks and a logic component connected in series to obtain an activated bit and (p−1) de-activated bits;
applying the activated bit and (p−1) de-activated bits to a number p of word lines of a first ROM array; and
when one of the number p of word lines is enabled by the activated signal, turning on a corresponding row of ROM cells so as to output the shift distance z in binary format by a number t of bit lines of the first ROM array, where t=roundup (log₂p);
wherein the encoder circuit comprises the number (p−2) of logic blocks, the logic component and the first ROM array; and
wherein the first ROM array comprises multiple ROM cells that are arranged in rows and columns configuration and store predefined binary codes in advance.

17. The method according to claim 14, wherein the step of shifting
receiving the 2p-bit second product by 2p input terminals of a barrel shifter comprising 2p output terminals and t multiplexing stages connected in cascaded;
shifting the 2p-bit second product to the left by the z bit positions by the t multiplexing stages to produce a 2p-bit shifted product at the 2p output terminals; and
outputting a p^{th} bit to a (2p−2)th bit of the 2p-bit shifted product at a number (p−1) of output terminals of the 2p output terminals as the (p−1)-bit significand of the first product;
wherein the 2p input terminals correspond to the 2p output terminals; and
wherein the encoder circuit comprises the barrel shifter, where t=roundup (log₂p).

18. The method according to claim 14, wherein the step of calculating comprises:
adding the (q+1)-bit temporary exponent and a value of 2 to obtain a (q+1)-bit sum; and
subtracting a value of (2^{q-1}+z) from the (q+1)-bit sum to obtain the q-bit exponent of the first product.

19. The method according to claim 14, wherein the step of performing multiplication comprises:
parallelly comparing a number 2²ⁿ of 2n-bit operand symbols hardwired in a second ROM array with a first n-bit digit and a second n-bit digit respectively selected from the first and the second p-bit significands to output one of a number 2²ⁿ of 2n-bit response symbols hardwired in a third ROM array as a 2n-bit product code by each of k² in-memory multiplier units in a parallel configuration so that a number k² of 2n-bit product codes are outputted in parallel from the k² in-memory multiplier units, wherein the number k² of 2n-bit product codes serve as 2n-bit first coefficients of a number k of first polynomials in base 2ⁿ and the 2n-bit first coefficients of each first polynomial in base 2ⁿ are associated with multiplication of the first p-bit significand with a corresponding digit of the second p-bit significand, wherein each of the first and the second p-bit significands has k digits in base 2ⁿ and k=p/n;
converting the 2n-bit first coefficients of the k first polynomials in base 2ⁿ into n-bit second coefficients of k second polynomials in base 2ⁿ in parallel by each of k binary adder circuits arranged in a parallel configuration; and
sequentially adding the n-bit second coefficients of the k second polynomials in base 2ⁿ in ascending degrees by a number (k−1) of polynomial adder circuits arranged in sequential order such that like terms of the k second polynomials in base 2ⁿ are lined up and added to generate n-bit third coefficients of a third polynomial in base 2ⁿ;
wherein the binary in-memory multiplier circuit comprising the k² in-memory multiplier units, the k binary adder circuits, and the number (k−1) of polynomial adder circuits;
wherein each of the k² in-memory multiplier units comprises the second ROM array and the third ROM array; and
wherein the n-bit third coefficients form the 2p-bit second product, and k and n are integers greater than 0.

20. The method according to claim 19, wherein the number 2²ⁿ of 2n-bit operand symbols and the number 2²ⁿ of 2n-bit response symbols define an n-bit by n-bit multiplication table.
